(19) United States
(12) Patent Application Publication
(10) Pub. No.: US 2026/0063714 A1
(43) Pub. Date: Mar. 5, 2026

(54) Scan Test Security for Semiconductor Devices

(71) Applicant: NVIDIA Corporation, Santa Clara, CA (US)

(72) Inventors: Vishal Agarwal, Santa Clara, CA (US); DooChul Shin, Sunnyvale, CA (US)

(73) Assignee: NVIDIA Corporation, Santa Clara, CA (US)

(21) Appl. No.: 19/267,933

(22) Filed: Jul. 14, 2025

Related U.S. Application Data
(60) Provisional application No. 63/688,859, filed on Aug. 29, 2024.

(51) Int. Cl. G01R 31/3185

(52) U.S. Cl. CPC G01R 31/318536; G01R 31/318588; G01R 31/318597

(57) ABSTRACT

A semiconductor device includes a scan data output and a scan chain having length n. Scan data bits appear sequentially at the scan data output responsive to a scan clock when the device is in a scan mode. Initial masking circuitry is operable to obscure, responsive to the device transitioning from a non-scan mode to the scan mode, a first n bits of the scan data appearing at the scan data output and not to obscure n+1st and subsequent bits of the scan data appearing at the scan data output. Infinite masking circuitry is operable to obscure, responsive to an infinite masking trigger, all scan data bits appearing at the scan data output until a reset of the device occurs. Monitoring and security enforcement circuitry is operable to detect a configuration change and to generate the infinite masking trigger if the detected change corresponds to a potential security risk.

### CROSS REFERENCE TO RELATED APPLICATIONS

This application claims benefit to the filing date of prior U.S. Patent Application No. 63/688,859, filed on 2024 Aug. 29 (the “Provisional Application”), the contents of which are hereby incorporated by reference as if entirely set forth herein; provided, however, that in the event of conflict between statements or terms appearing in this document and statements or terms appearing in the Provisional Application or in another document incorporated herein by reference, the statements or terms appearing in this document shall control.

### BACKGROUND

A variety of tests may be employed to verify functionality and correctness in a semiconductor device.

One such test is typically applied at the time of manufacture and is performed to verify low-level aspects of a device such as whether the circuits housed in the device have been assembled correctly based on building blocks that were specified in a structural netlist prior to its fabrication. This type of test is referred to variously as “structural pattern testing,” “structural test,” or “scan test” because it involves serially scanning a test pattern (a series of logical 1s and 0s) into scan cells housed in the device package. More particularly, flip flop elements in a device implement the scan cells, and the scan cells are linked together in series fashion to form a scan chain. When the device is placed in a scan mode, the scan cells in the scan chain function as a large shift register that enables a test pattern to be clocked into the scan cells that form the chain. Once the test pattern has been loaded into the scan cells, the device may be placed in a scan capture mode in which the loaded test pattern provides stimulus for core logic in the device while a corresponding test response is captured over one or more clock cycles of operation. After this has been accomplished, the device may once again be placed in the scan mode, and the captured test response may be shifted out of the scan cells for analysis by another system, such as by an automated test equipment (“ATE”) platform.

Because scan cell coverage for semiconductor devices is often very thorough, the contents of the scan cells within a device can under certain circumstances reveal information about the design or the behavior of the core logic in the device. Consequently, a number of scan-based security exploits have been discovered whose purpose is to extract scan cell contents from semiconductor devices and thereby to reverse engineer or otherwise gather sensitive information about the devices. See, for example, Li, et al., “Scan Chain Based Attacks and Countermeasures: A Survey,”IEEE Access, Vol. 7, pp. 85055-85065 (IEEE 2019).

A need therefore exists for features that can enhance security in relation to scan test functionality in semiconductor devices and that can help to prevent scan-based security attacks.

### BRIEF DESCRIPTION OF THE DRAWINGS

FIG. 1 is a block diagram schematically illustrating an example semiconductor device that includes scan test functionality and security logic in accordance with embodiments.

FIG. 2 is a block diagram schematically illustrating an example scan chain in accordance with embodiments.

FIG. 3 is a block diagram schematically illustrating an example configurable scan chain in accordance with embodiments.

FIG. 4 is a block diagram schematically illustrating an example implementation of the security logic of FIG. 1, in accordance with embodiments.

FIG. 5 is a state diagram illustrating possible states in the semiconductor device of FIG. 1, in accordance with embodiments.

FIG. 6 is a schematic diagram illustrating an example implementation of the monitoring and security enforcement circuitry of FIG. 4, in accordance with embodiments.

FIG. 7 is a flow diagram illustrating a class of methods for reducing security vulnerabilities in a semiconductor device, in accordance with embodiments.

### DETAILED DESCRIPTION

This disclosure describes multiple embodiments by way of example and illustration. It is intended that characteristics and features of all described embodiments may be combined in any manner consistent with the teachings, suggestions, and objectives contained herein. Thus, phrases such as “in an embodiment,” “in one embodiment,” and the like, when used to describe embodiments in a particular context, are not intended to limit the described characteristics or features only to the embodiments appearing in that context. Although numerous specific example embodiments are described below, it is intended that any one or more of the features or elements of each described embodiment may be combined with or substituted for any one or more of the features or elements of another described embodiment, in any desired combinations. The scope of the disclosure is intended to include all such combinations, modifications, and generalizations as well as their equivalents.

The phrases “based on” or “based at least in part on” refer to one or more inputs that can be used directly or indirectly in making some determination or in performing some computation. Use of those phrases herein is not intended to foreclose using additional or other inputs in making the described determination or in performing the described computation. Rather, determinations or computations so described may be based either solely on the referenced inputs or on those inputs as well as others.

The phrases “configured to” and “operable to” as used herein mean that the referenced item, when operated, can perform the described function. In this sense, an item can be “configured to” or “operable to” perform a function even when the item is not operating and therefore is not currently performing the function. Use of the phrase “configured to” herein does not necessarily mean that the described item has been modified in some way relative to a previous state.

“Coupled” as used herein refers to a connection between items. Such a connection can be direct or can be indirect, such as through connections with other intermediate items.

Terms used herein such as “including,” “comprising,” and their variants, mean “including but not limited to.”

Articles of speech such as “a,” “an,” and “the” as used herein are intended to serve as singular as well as plural references except where the context clearly indicates otherwise. For example, articles of speech such as “a,” “an,” and “the,” when used in a claim or sentence subsequent to words such as “including,” “comprising,” or their variants, mean “one or more” unless modified by phrases such as “exactly one” or “one and only one.”

The phrase “JTAG standards” as used herein refers to a set of standards that have been developed to foster uniformity in the equipment used to perform scan testing and to increase the efficiency of designers tasked with supporting scan testing. Among these are a suite of Joint Test Action Group (“JTAG”) standards, including an IEEE 1687 Internal JTAG standard, an IEEE 1149.1 Boundary Scan standard, and an IEEE 1500 Embedded Core Test standard, among others.

The phrases “design-for-test logic,” “DFT circuitry,” and the like as used herein refer to circuitry that may be included in a semiconductor device to implement scan chain functionality. For example, design-for-test logic may implement a conventional JTAG interface and associated conventional JTAG-related components, and may also implement inventive features to be further described below.

### EXAMPLE EMBODIMENTS

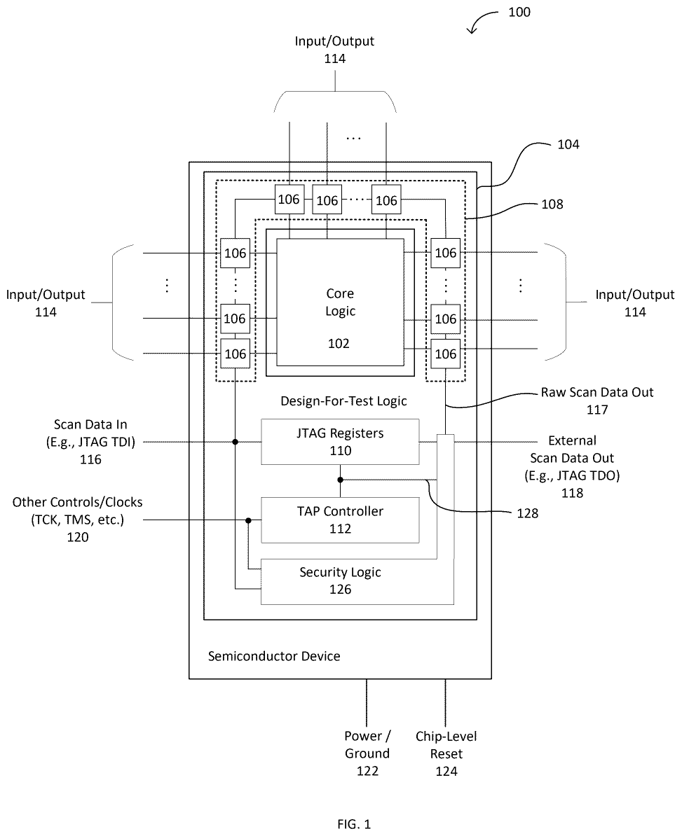

FIG. 1 is a block diagram schematically illustrating an example semiconductor device 100 according to embodiments. The device includes at least one core logic block 102 configured to implement functions that the semiconductor device is intended to provide. For example, the core logic may implement the functions of a central processing unit (“CPU”), a graphics processing unit (“GPU”), or any other types of functions, including application-specific functions such as those of a dedicated controller. The device also includes design-for-test (“DFT”) logic 104.

In the illustrated embodiment, the DFT logic includes several scan cells 106 that are linked together serially to collectively form a scan chain 108. Each scan cell may be coupled to an input/output pin or pad 114 of the device and may also be coupled to the core logic, as shown. The DFT logic may include JTAG registers 110 and a test access port (“TAP”) controller 112, for example, as those are described by the JTAG standards. The JTAG registers may include an instruction register, data registers such as a boundary scan register (“BSR”), a bypass register, and an ID codes register, also as described by the JTAG standards. In some embodiments, the JTAG registers may also include application specific control and/or data registers beyond those described by the JTAG standards, if necessary or desirable for particular applications. The device includes a scan data input 116, such as a JTAG test data in (“TDI”) port, a scan data output 118, such as a JTAG test data out (“TDO”) port, and several address/control and/or clock signals 120 such as a JTAG test clock (“TCK”), a test mode select (“TMS”) signal, and a test reset (“TRST”) signal. One or more power/ground pins or pads 122 are provided to power the device, and a chip-level reset pin or pad 124 is provided to reset the device to a desired initial state.

Semiconductor device 100 further includes security logic 126 that implements components and functionality to be further described herein. The security logic is coupled to a raw scan data output 117 of the scan chain as well as to the external scan data output 118 of the device. The security logic is also coupled to signals that may be used to manage the configuration of device 100, including any signals that may be used to manipulate the contents of registers that control the configuration of elements within the device, such as elements that are related to the scan test functionality of the device. In the illustrated embodiment, for example, the security logic is coupled to scan data input 116, to control/clock signals 120, and to signals 128 that affect the configuration and contents of the JTAG registers.

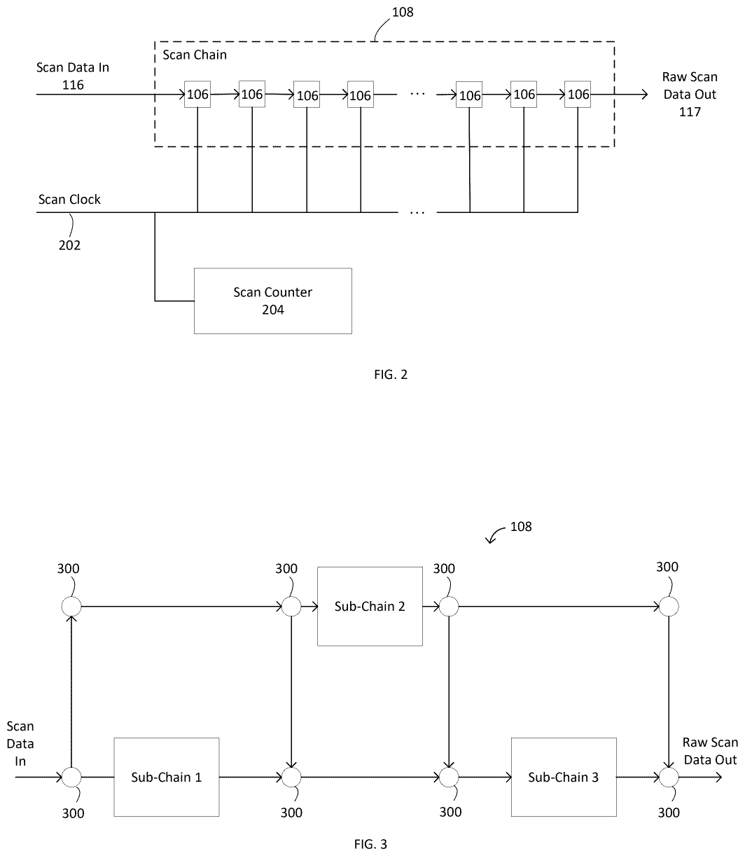

Scan chain 108 may take a variety of forms in different embodiments, and more than one scan chain may be provided in the same device in any embodiments. Moreover, scan chain 108 may be configurable. FIGS. 2 and 3 help to illustrate this by way of example and not by way of limitation.

Referring now to FIG. 2, the “length” of a scan chain 108 refers to the number of scan cells that are included in the chain. For example, the scan chain illustrated in FIG. 2 includes seven scan cells. It thus has a length of seven. Moreover, each scan cell in a scan chain typically stores one digital bit of information. Thus, the scan chain illustrated in FIG. 2 would contain seven digital bits of information. As the ellipses in FIGS. 1 and 2 signify, however, a scan chain 108 may generally include any number of scan cells (e.g., hundreds, thousands, or millions of cells) and may also be configurable such that its length and its contents can vary according to its current configuration.

Typically, each scan cell is coupled to a scan clock 202 to facilitate shifting scan data bits (scan cell contents) in serial fashion from one scan cell to another during a shift operation, or to facilitate loading bits into the scan cells in parallel fashion from respective inputs such as device inputs 114 during a load operation, all under the control of the TAP controller and in accordance with settings contained in the associated JTAG registers. One or more scan counters 204 may also be provided to count the number of scan data bits that are shifted out of the scan chain during a shift operation.

FIG. 3 is provided to illustrate, by way of example, how the length and/or the contents of a scan chain 108 may be configured in a semiconductor device. As the example shows, in general a scan chain 108 may comprise two or more sub-chains such as sub-chains 1, 2, and 3, and switching elements 300 may be provided along with interconnecting conductors such that an aggregate scan chain may be created based on various combinations of the sub-chains. Configuration of the switching elements may be performed by writing suitable control words to configuration registers in device 100. In some embodiments, such configuration may be accomplished using the JTAG interface, which comprises scan data in signal 116, scan data out signal 118, and clock and control signals 120. In other embodiments, other means may be used to accomplish the configuration. In still further embodiments, various clocks and counters in device 100, such as scan clock 202 and scan counter 204, may also be configurable. For example, in some embodiments, a clock may be paused or a counter may be paused or reset based on a current configuration of the device.

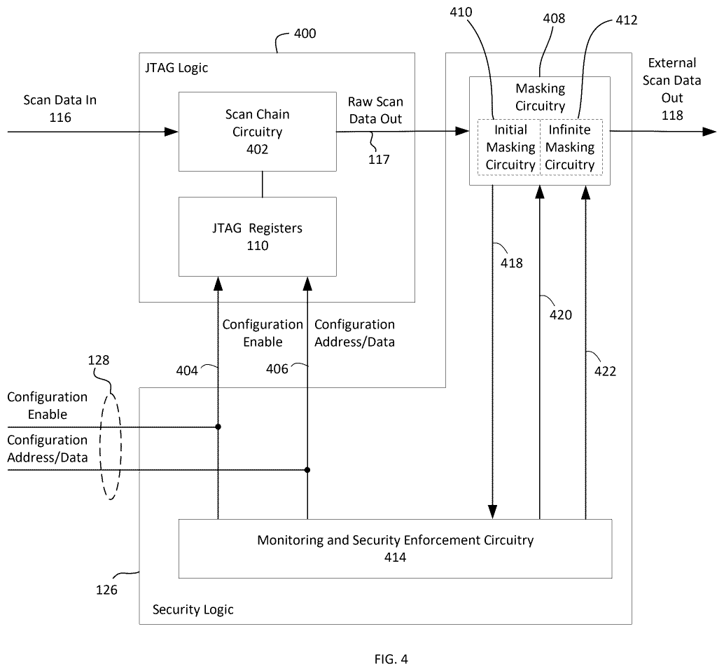

Referring now to FIG. 4, an example embodiment of security logic 126 will now be described in more detail. In the embodiment illustrated, JTAG logic 400 includes scan chain circuitry 402 and JTAG registers 110. Scan chain circuitry 402 may include, for example, one or more scan chains 108 or sub-chains and associated switching elements 300. The scan chain circuitry is coupled to scan data input 116 and produces raw scan data output 117, as shown. Configuration and contents of the scan chain circuitry may be controlled by writing appropriate values into the JTAG registers by means of address/enable/control signals 128. Signals 128 may include, for example, a configuration enable signal 404 to indicate whether configuration of the JTAG registers is currently enabled, and a set of address/data signals 406 that may be used to modify contents of the JTAG registers when the configuration enable signal is asserted.

Inside security logic 126, raw scan data output 117 is coupled to masking circuitry 408. In the illustrated embodiment, masking circuitry 408 includes initial masking circuitry 410 and infinite masking circuitry 412. In any embodiments, the initial masking circuitry and the infinite masking circuitry may be implemented in a variety of ways. For example, in some embodiments, they may be implemented as separate subsystems. In other embodiments, they may be implemented with a single subsystem operable in a first mode to perform an initial masking function and in a second mode to perform an infinite masking function. Both functions are further described below.

The security logic also includes monitoring and security enforcement circuitry 414, which may be coupled to any signals that may be used to effect a change in a configuration of device 100. Thus, in the illustrated example, the monitoring and security enforcement circuitry is coupled to configuration enable signal 404 and to configuration address/data signals 406. In other embodiments, the monitoring and security enforcement circuitry may be coupled to additional or different configuration signals.

In various embodiments, the functions of the masking circuitry may be controlled in different ways. In the illustrated embodiment, monitoring and security enforcement circuitry 414 controls the operation of the masking circuitry, and does so with reference to a sticky masking activated signal 418 that it receives from the masking circuitry and by generating an initial masking trigger 420 and an infinite masking trigger 422 for consumption by the masking circuitry.

The masking activated signal and the initial masking and infinite masking triggers may also take any of a wide variety of suitable forms. In the embodiment shown, the masking activated signal and each of the triggers are illustrated as respective single-bit digital control signals for simplicity of explanation. In other embodiments, any one or more of them may correspond simply to a state, to a state transition, or to state transition control signals in one or more state machines that control the masking circuitry and/or the monitoring and security enforcement circuitry. In still other embodiments, any one or more of the triggers may correspond to a distinct command or to an asserted signal. In still further embodiments, any one or more of the triggers may correspond to a single bit or to a multibit value that is applied to a control input of another subsystem in device 100 or that is written to a control or a data register in device 100. Other implementations are also possible.

Referring now to FIG. 5, device 100 may operate in any one of several possible states or modes at a given point in time. Upon power-up, or when chip-level reset 124 is asserted, the device may enter a chip-level reset mode 500. In the reset mode, various initial device configurations may be performed based on values written to configuration registers either before the device enters the reset mode or while the device remains in the reset mode. Thereafter, the device may enter any of several possible scan modes 502 or other modes 504 based on control signals and/or clock signals applied to respective input pins or pads of the device. In general, a device 100 may transition between any of modes 500, 502, or 504 based on appropriate clock and control inputs applied to the device, as indicated by the arrows in FIG. 5.

Scan modes 502 may include any of several modes in which the scan-related functionality in the device is made available. The scan modes may correspond, for example, to any of the TAP controller states indicated by the JTAG standards, such as the select data register (“Select DR”) state, the capture data register (“Capture DR”) state, the shift data register (“Shift DR”) state, or the update data register (“Update DR”) state, any one or more of which may be used to cause scan data bits to be shifted serially from the scan chain to the raw scan data output or to be loaded into the scan chain from the device input pins/pads or from a JTAG data register.

Modes 504 may include any of several modes in which the scan-related functionality in the device is not available. For example, modes 504 may include a normal operating mode in which the device is used to perform the functions that its core logic was intended to provide.

In operation, when device 100 transitions to any of scan modes 502 from any other mode (e.g., from any of modes 500 or modes 504) for the first time since a most recent device reset or power-up, security logic 126 activates initial masking circuitry 410. As was described above, it may do so by any suitable means, such as by generating or asserting an initial masking trigger 420. While initial masking circuitry 410 is active, the initial masking circuitry functions in a first phase to obscure the first n bits of scan data appearing at external scan data output 118 since the device has entered the scan mode, where n corresponds to a currently-configured length of a scan chain in scan chain circuitry 402. Once the first n scan data bits have been “clocked out” of the device in obscured fashion, the initial masking circuitry functions in a second phase to allow any further scan data bits (i.e., the n+1^{st} and subsequent scan data bits clocked out after the device has entered a scan mode) to pass to the external scan data output unobscured.

In general, the masking circuitry may obscure scan data bits in any suitable fashion. In some embodiments, it may do so by forcing the bits appearing at the external scan data output to logical 0s or to logical 1s. In other embodiments, it may tristate the external scan data output. Other implementations are also possible.

In the embodiment illustrated in FIG. 4, masking circuitry 408 asserts the sticky masking activated signal 418 once the initial masking circuitry has been activated. The masking activated signal is sticky in the sense that the signal, once asserted, will remain asserted even after the first n bits of scan data appearing at the external scan data output have been obscured and subsequent scan data bits have been clocked out of the device unobscured.

While device 100 is operating in either of the first or the second phases of the initial masking mode, monitoring and security enforcement circuitry 414 continuously monitors to detect whether a configuration of the device is being changed. It may do so in a variety of ways. In the embodiment illustrated in FIG. 4, it does so by monitoring JTAG register control, address, or data signals 128.

If a determination is made that a configuration of the device is being changed, then the monitoring and security enforcement circuitry further determines whether or not the detected device configuration change corresponds to a potential security risk. As persons having skill in the art and having reference to this disclosure will appreciate, the particular configuration changes that may correspond to a scan-related security risk may vary in different embodiments. For example, in some embodiments, changing the length of a scan chain in the device or changing the sub-chains that are included in a scan chain in the device may present a security risk. In some embodiments, pausing or reconfiguring a clock or a scan counter in the device while another clock or counter is permitted to advance may present a security risk. In still further embodiments, causing one functional block in the device to believe the device is in a scan mode while another functional block in the device believes the device is in a non-scan mode may present a security risk. A variety of other such risks are possible given the characteristics of a particular device and the nature of any potential scan-related security attacks that might be attempted on such a device. All such risks may be detected by monitoring the device for corresponding configuration changes as described herein.

In the illustrated embodiment, any configuration change that could alter a configuration of the scan chain in scan chain circuitry 402 may be categorized as potentially harmful. This is because such a configuration change could result in either the length of the scan chain being altered or could result in an alteration of which sub-chains are included in the scan chain, as was explained above, for example, in relation to FIG. 3. In further embodiments, any configuration change that could alter a configuration of a clock signal, such as scan clock 202, or a scan counter, such as scan counter 204, may be categorized as potentially harmful. This is because such a configuration change could result, for example, in a scan counter reporting an erroneous value.

The mechanisms used to identify a given configuration change as a potential security risk may also vary with embodiments. In some embodiments, the determination may be made by identifying to which of several possible configuration change categories a detected configuration change belongs, and then by comparing the determined category with a “whitelist” of harmless configuration change categories. If the detected configuration change corresponds to a whitelisted (i.e., a harmless) category, then operation of the device may continue in the initial masking mode. If, however, the detected configuration change corresponds to a potentially harmful configuration change (i.e., to a non-whitelisted category), then the monitoring and security enforcement circuitry may activate infinite masking circuitry 412. As was described above, the mechanism used to activate the infinite masking circuitry may vary in embodiments. In the embodiment illustrated in FIG. 4, the monitoring and security enforcement circuitry activates the infinite masking circuitry by generating or asserting a one-bit infinite masking trigger signal 422.

Once infinite masking circuitry 412 has been activated, masking circuitry 408 functions to obscure all scan data bits appearing at the external scan data output of the device until the next reset of the device occurs. The infinite masking circuitry, once activated, overrides the initial masking circuitry and remains active until the device is reset.

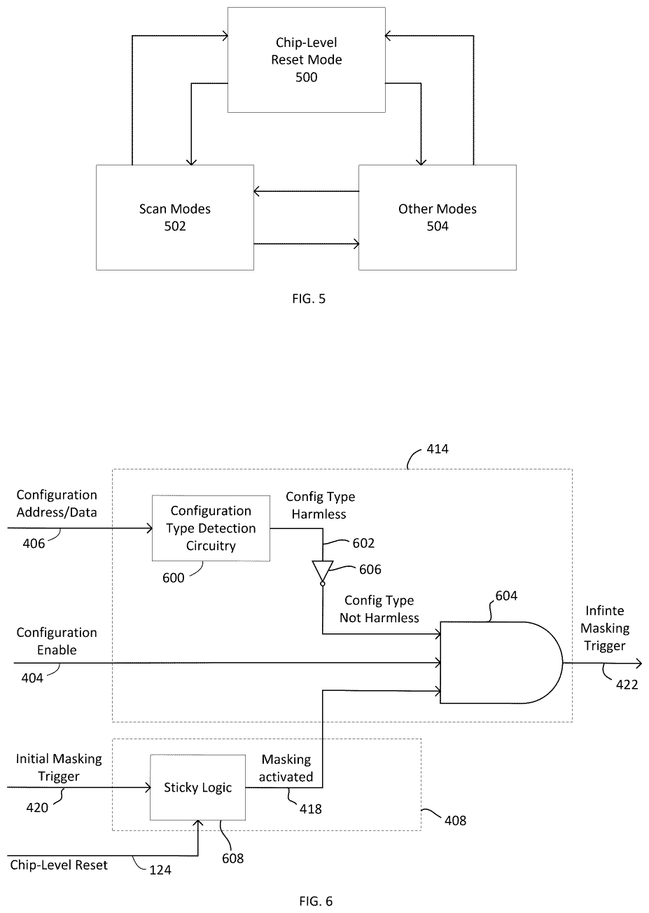

FIG. 6 illustrates, by way of example, one possible implementation for generating an infinite masking trigger in embodiments. Referring now to FIG. 6, monitoring and security enforcement circuitry 414 may use configuration enable signal 404 to detect if a configuration of device 100 is being changed. Configuration type detection circuitry 600 may also be provided within the monitoring and security enforcement circuitry to determine if a state of address/data signals 406 corresponds to a potential security risk. It may do so, for example, in accordance with the description provided above and may generate a whitelist signal 602 to indicate whether or not the configuration change corresponds to a potential security risk. In various embodiments, the monitoring and enforcement circuitry may assert infinite masking trigger 422 based on a state of the whitelist signal or its inverse (see, for example, AND gate 604 and inverter 606).

A sticky logic block 608 may be provided in some embodiments to assert masking activated signal 418 once initial masking trigger 420 has been asserted, and to keep the masking activate signal asserted until the next chip level reset occurs. In such embodiments, the monitoring and security enforcement circuitry may assert the infinite masking trigger based on a logical combination of a state of the masking activated signal and the state of the whitelist signal or its inverse (again, see AND gate 604 and inverter 606).

In the illustrated embodiment, the infinite masking signal is implemented as a one-bit digital signal that is asserted based on the logical AND of the following: configuration enabled signal 404, masking activated signal 418, and the inverse of the state of whitelist signal 602. In other embodiments, other means may be employed to trigger the infinite masking functionality.

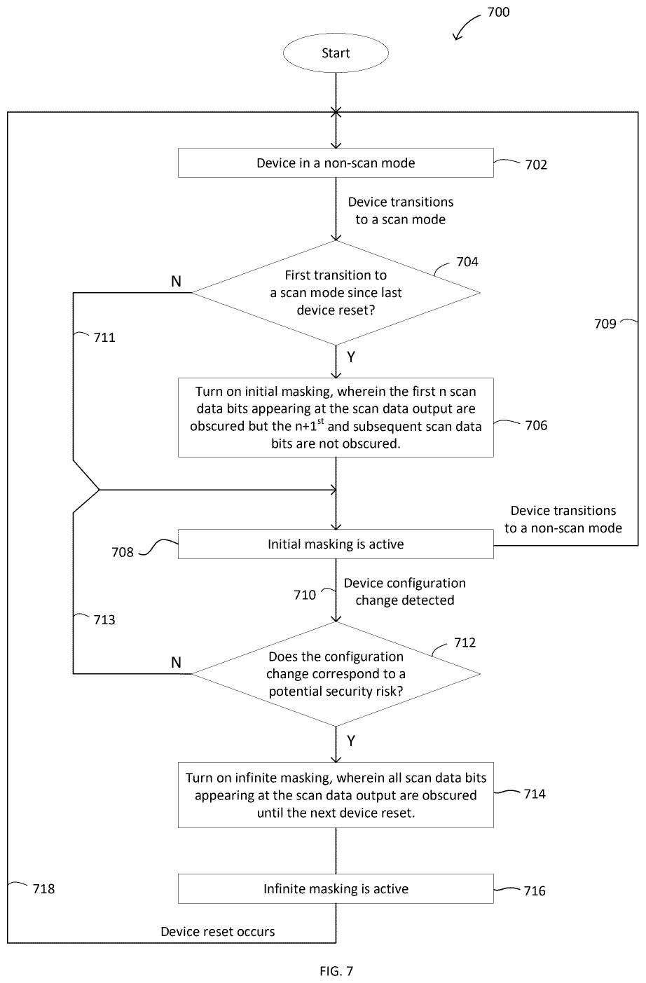

FIG. 7 illustrates a class of methods 700, consistent with the above, for reducing security vulnerabilities in a semiconductor device such as device 100.

The methods begin at step 702, in which the device powers up in, or enters, a non-scan mode. The device may enter this mode, for example, in response to a device reset signal or as a default behavior after a power-up of the device, as was described above.

Thereafter, upon the first transition of the device to a scan mode in which scan data bits may appear sequentially at an external scan data output of the device responsive to a scan clock (see decision 704), initial masking functionality is turned on at step 706, after which the initial masking functionality remains active (see step 708 and arrows 709, 711, and 713) unless and until infinite masking is triggered or a device reset occurs. When initial masking is active, the first n scan data bits appearing at the external scan data output of the device are obscured, but the n+1^{st} and subsequent scan data bits appearing at the external scan data output are not obscured.

While the device is in the initial masking mode, the device continues to monitor to detect whether a configuration change in the device is occurring. If such a change is detected (see arrow 710), a determination is made whether the detected configuration change corresponds to a potential security risk (see decision 712). If the detected configuration change is determined to correspond to a potential security risk, the device turns on infinite masking functionality at step 714. Thereafter, infinite masking remains in effect until a next reset of the device occurs (see step 716). When infinite masking is active, all scan data bits appearing at the external scan data output of the device are obscured until the next device reset occurs (see arrow 718).

### Conclusion

Multiple specific embodiments have been described above and in the appended claims. Such embodiments have been provided by way of example and illustration. Persons having skill in the art and having reference to this disclosure will perceive various utilitarian combinations, modifications and generalizations of the features and characteristics of the embodiments so described. For example, steps in methods described herein may be performed in any order, and some steps may be omitted, while other steps may be added, except where the context clearly indicates otherwise. Similarly, components in structures described herein may be arranged in different positions or locations, and some components may be omitted, while other components may be added, except where the context clearly indicates otherwise. The scope of the disclosure is intended to include all such combinations, modifications, and generalizations as well as their equivalents.

What is claimed is:

1. A method for reducing security vulnerabilities in a semiconductor device, comprising:
responsive to the device transitioning from a non-scan mode to a scan mode in which scan data bits may appear sequentially at a scan data output of the device responsive to a scan clock, obscuring a first n bits of the scan data appearing at the scan data output and not obscuring n+1st and subsequent scan data bits appearing at the scan data output, wherein n corresponds to a length of a scan chain in the device;
detecting if a configuration of the device is being changed;
determining if a detected configuration change corresponds to a potential security risk; and
responsive to determining that the detected configuration change corresponds to a potential security risk, obscuring all scan data bits appearing at the scan data output until a reset of the device occurs.

2. The method of claim 1, wherein:
detecting if a configuration of the device is being changed comprises monitoring signals in the device that are operable to change its configuration.

3. The method of claim 2, wherein:
the signals comprise JTAG register control, address, or data signals.

4. The method of claim 1, wherein:
obscuring scan data bits appearing at the scan data output comprises forcing the scan data bits appearing at the scan data output to logical 1s or 0s.

5. The method of claim 1, wherein:
determining if a detected configuration change corresponds to a potential security risk comprises determining if the detected configuration change would change a configuration of the scan chain.

6. The method of claim 5, wherein:
determining if a detected configuration change corresponds to a potential security risk comprises determining if the detected configuration change would change the length of the scan chain.

7. The method of claim 1, wherein:
determining if a detected configuration change corresponds to a potential security risk comprises determining if the detected configuration change would change a configuration of a clock or a scan counter.

8. The method of claim 1, wherein:
obscuring all scan data bits appearing at the scan data output until a reset of the device occurs comprises the device entering an infinite masking mode that is enabled only after the device has transitioned from the non-scan mode to the scan mode at least once after a most recent reset of the device has occurred.

9. The method of claim 8, wherein:
determining if a detected configuration change corresponds to a potential security risk comprises generating a whitelist signal to indicate whether the detected configuration change is harmless; and
entering the infinite masking mode comprises generating an infinite masking trigger based on a state of the whitelist signal or its inverse.

10. The method of claim 9, wherein:
detecting if a configuration of the device is being changed comprises generating a configuration enabled signal to indicate whether a device configuration change is currently enabled; and
generating the infinite masking trigger is further based on a state of the configuration enabled signal.

11. The method of claim 8:
further comprising generating a masking activated signal to indicate whether the device has transitioned from the non-scan mode to the scan mode at least once after a most recent reset of the device has occurred; and
generating the infinite masking trigger is further based on a state of the masking activated signal.

12. A semiconductor device, comprising:
a scan chain and a scan data output, wherein scan data bits may appear sequentially at the scan data output responsive to a scan clock when the device is in a scan mode;
initial masking circuitry operable to obscure, responsive to the device transitioning from a non-scan mode to the scan mode, a first n bits of the scan data appearing at the scan data output and not to obscure n+1st and subsequent bits of the scan data appearing at the scan data output, wherein n corresponds to a length of the scan chain;
infinite masking circuitry operable to obscure, responsive to an infinite masking trigger, all scan data bits appearing at the scan data output until a reset of the device occurs;
monitoring and security enforcement circuitry operable to detect if a configuration of the device is being changed and to generate the infinite masking trigger if a detected configuration change corresponds to a potential security risk.

13. The semiconductor device of claim 12, wherein:
the monitoring and security enforcement circuitry is coupled to JTAG register control, address, or data signals in the device and is operable to detect a configuration change based on states of the JTAG register control, address, or data signals.

14. The semiconductor device of claim 12, wherein:
the monitoring and security enforcement circuitry is configured to generate the infinite masking trigger if a detected configuration change would change a configuration of the scan chain.

15. The semiconductor device of claim 14, wherein:
the monitoring and security enforcement circuitry is configured to generate the infinite masking trigger if a detected configuration change would change the length of the scan chain.

16. The semiconductor device of claim 12, wherein:
the monitoring and security enforcement circuitry is configured to generate the infinite masking trigger if a detected configuration change would change a configuration of a clock or a scan counter.

17. The semiconductor device of claim 12, wherein:
the infinite masking circuitry is enabled only after the device has transitioned from the non-scan mode to the scan mode at least once after a most recent reset of the device has occurred.

18. The semiconductor device of claim 12:
further comprising configuration type detection circuitry operable to generate a whitelist signal indicating whether the detected configuration change is harmless; and
wherein the monitoring and security enforcement circuitry is configured to generate the infinite masking trigger based on a state of the whitelist signal or its inverse.

19. The semiconductor device of claim 18:
further comprising a masking activated signal operable to indicate whether the device has transitioned from the non-scan mode to the scan mode at least once after a most recent reset of the device has occurred; and
wherein the monitoring and security enforcement circuitry is configured to generate the infinite masking trigger based on a logical combination of a state of the masking activated signal and the state of the whitelist signal or its inverse.

20. The semiconductor device of claim 19:
further comprising a configuration enabled signal operable to indicate whether a device configuration change is currently enabled; and
wherein the monitoring and security enforcement circuitry is configured to generate the infinite masking trigger based on a logical combination of a state of the configuration enabled signal, the state of the masking activated signal, and the state of the whitelist signal or its inverse.

21. The semiconductor device of claim 12, wherein:
the infinite masking trigger comprises a one-bit digital signal.
